(19) United States
(12) Patent Application Publication
(10) Pub. No.: US 2004/0008068 A1
(43) Pub. Date: Jan. 15, 2004

(54) Flip-flop for high-speed operation

(75) Inventor: Min-su Kim, Kyungki-do (KR)

Correspondence Address: Steven M. Mills, MILLS & ONELLO LLP, Suite 605, Eleven Beacon Street, Boston, MA, 02108, US

(73) Assignee: Samsung Electronics Co., Ltd.

(21) Appl. No.: 10/452,713

(22) Filed: Jun. 2, 2003

(30) Foreign Application Priority Data
Jul. 12, 2002 (KR) 02-40847

(51) Int. Cl. H03K 3/037

(52) U.S. Cl. 327/218

(57) ABSTRACT

Provided is a flip-flop capable of operating at high speed by reducing a clock-to-output delay. The flip-flop includes a sense amplifier and a latch circuit. The sense amplifier includes a first node and a second node, precharges the first node and the second node with a supply voltage according to a state of a clock signal, or receives and amplifies differential input signals according to the state of the clock signal, so as to output differential output signals to the first node and the second node. The latch circuit is connected to the first node and the second node, and detects and latches the differential input signals according to the state of the clock signal and the differential output signals. The flip-flop described above does not use a NAND gate, so that a clock-to-output delay can be reduced. Therefore, the flip-flop has an advantage of operating at high speed.

### BACKGROUND OF THE INVENTION

This application claims the priority of Korean Patent Application No. 2002-40847, filed Jul. 12, 2002, which is incorporated herein in its entirety by reference.

1. Field of the Invention

The present invention relates to a flip-flop implemented on a semiconductor chip, and more particularly, to a flip-flop enabling high-speed operation by reducing a clock-to-output delay.

2. Description of the Related Art

FIG. 1 is a circuit diagram of a general SAFF (sense amplifier-based flip-flop; hereinafter referred to as “SAFF”). Referring to FIG. 1, the SAFF, which is well known in this field, includes a sense amplifier 10 in a first stage and an R-S latch 20 in a second stage.

If a clock signal CLK is at a low level, a set node \overline{S} and a reset node \overline{R} are precharged respectively with a supply voltage VDD.

At a rising edge of the clock signal CLK, the sense amplifier 10 senses differential signals D and \overline{D}. One of the set node \overline{S} and the reset node \overline{R} transmits monotonously from the supply voltage VDD to a low level (e.g., a ground voltage), and the other node maintains the supply voltage VDD.

The R-S latch 20 captures each transition and maintains a captured state immediately before a next rising edge of the clock signal CLK.

In a case where the set node \overline{S} is at a low level, an output signal Q turns into the supply voltage VDD and an output signal \overline{Q} turns into a low level by a NAND (Negative AN-D) gate. In a case where the reset node \overline{R} is at a low level, the output signal \overline{Q} goes to the level of the supply voltage VDD and the output signal Q turns into a low level by the NAND gate.

Therefore, one of the output signals Q and \overline{Q} always has a delay of one NAND gate in comparison to the other output signal. In a high-to-low transition, a clock-to-output delay is the same as a delay caused by three gates. In a low-to-high transition, the clock-to-output delay is the same as the delay cased by two gates. Therefore, the high-to-low transition restricts high-speed operation of a conventional SAFF.

### SUMMARY OF THE INVENTION

It is an object of the present invention to provide a flip-flop capable of performing high-speed operation by reducing a clock-to-output delay.

In one aspect, the present invention provides a flip-flop comprising a sense amplifier which includes a first node and a second node, that are precharged with a supply voltage according to a state of a clock signal, or receive and amplify differential input signals according to the state of the clock signal, so as to output differential output signals to the first node and the second node. The flip-flop also includes a latch circuit which is connected to the first node and the second node of the sense amplifier and which detects and latches the differential input signals according to the state of the clock signal and the differential output signals.

In one embodiment, the latch circuit comprises a first output node, a second output node, a first pull-up circuit which pulls up the first output node to a supply voltage in response to a signal of the first node, a second pull-up circuit which pulls up the second output node to the supply voltage in response to a signal of the second, node, a first pull-down circuit which pulls down the first output node to a ground voltage in response to the signal of the first node and the state of the clock signal, a second pull-down circuit which pulls down the second output node to the ground voltage in response to the signal of the second node and the state of the clock signal and a data latch circuit which latches a signal of the first output node and a signal of the second output node.

In one embodiment, the latch circuit comprises a first output node, a second output node, a first PMOS transistor connected between the supply voltage and the first output node, a gate of which is connected to the first node of the sense amplifier, a first NMOS transistor and a second NMOS transistor which are connected in series between the first output node and a ground voltage, a second PMOS transistor connected between the supply voltage and the second output node, a gate of which is connected to the second node of the sense amplifier, a third NMOS transistor and a fourth NMOS transistor connected in series between the second output node and the ground voltage, a first inverter of, an input terminal of which is connected to the first output node and an output terminal of which is connected to the second output node and a second inverter, the input node of which is connected to the second output node and an output terminal of which is connected to the first output node, wherein the clock signal is inputted to the gate of the first NMOS transistor and the gate of the third transistor, the gate of the second NMOS transistor is connected to the first node, and the fourth NMOS transistor is connected to the second node.

The latch circuit can comprise a first output node, a second output node, a first pull-down circuit which pulls down the first output node to a ground voltage in response to a signal of the first node, a first pull-up circuit which pulls up the first output node to the supply voltage in response to the signal of the second node, a second pull-down circuit which pulls down the second output node to the ground voltage in response to a signal of the second node, a second pull-up circuit which pulls up the second output node to the supply voltage in response to the signal of the first node and a data latch circuit which latches a signal of the first output node and a signal of the second output node.

The latch circuit can comprise a first output node, a second output node, a first PMOS transistor is connected between the supply voltage and the first output node, a gate of which is connected to the second node of the sense amplifier, a second PMOS transistor connected between the first output node and the ground voltage, a gate of which is connected to the first node, a third PMOS transistor which is connected between the supply voltage and the second output node and of which gate is connected to the first node, a fourth PMOS transistor connected between the second output node and the ground voltage, a gate of which is connected to the second node of the sense amplifier, a first inverter, an input terminal of which is connected to the first output node and an output terminal of which is connected to the second output node and a second inverter, an input terminal of which is connected to the second output node and an output terminal of which is connected to the first output node.

According to another aspect, the invention is directed to a flip-flop comprising a sense amplifier which includes a first node and a second node, that are precharged with a supply voltage according to a state of a first clock signal, or receive and amplify differential input signals according to the state of the first clock signal, so as to output differential output signals to the first node and the second node and a latch circuit which is connected to the first node and the second node of the sense amplifier, detects and latches the differential input signals according to the state of the second clock signal and the differential output signals.

The latch circuit can comprise a first output node, a second output node, a first pull-up circuit which pulls up the first output node to a supply voltage in response to a signal of the first node, a second pull-up circuit which pulls up the second output node to the supply voltage in response to a signal of the second node, a first pull-down circuit which pulls down the first output node to a ground voltage in response to the signal of the first node and the state of the second clock signal, a second pull-down circuit which pulls down the second output node to the ground voltage in response to the signal of the second node and the state of the second clock signal and a data latch circuit which latches a signal of the first output node and a signal of the second output node.

According to another aspect, the invention is directed to a flip-flop comprising a sense amplifier which includes a pair of input nodes and a pair of output nodes, that are precharged with a supply voltage according to a state of a clock signal, or receive and amplify differential input signals inputted to the pair of input nodes according to the state of the clock signal, so as to output differential output signals to the pair of output nodes and a latch circuit which is connected to the pair of output nodes of the sense amplifier, detects and latches the differential input signals inputted to the pair of input nodes of the sense amplifier according to the state of the clock signal and the differential output signals from the pair of output nodes.

According to another aspect, the invention is directed to a flip-flop comprising a sense amplifier which senses and amplifies differential input signals inputted to a first input node and a second input node and outputs differential output signals, which are the results of the amplification, to a first node and a second node, in an evaluation mode and a latch circuit connected to the first node and the second node, which detects and latches the differential input signals according to the state of the differential output signals, in the evaluation mode.

The flip-flop is characterized by precharging the first node and the second node with a supply voltage in a precharging mode, wherein in the precharging mode, the latch circuit latches the detected differential input signals immediately before the next evaluation mode.

The latch circuit can comprise a first output node, a second output node, a first pull-up circuit which pulls up the first output node to a supply voltage in response to a signal of the first node, a second pull-up circuit which pulls up the second output node to the supply voltage in response to a signal of the second node, a first pull-down circuit which pulls down the first output node to a ground voltage in response to the signal of the first node, a second pull-down circuit which pulls down the second output node to the ground voltage in response to the signal of the second node and a data latch circuit which latches a signal of the first output node and a signal of the second output node.

The latch circuit can comprise a first output node, a second output node, a first PMOS transistor which is connected between the supply voltage and the first output node, the gate of which is connected to the first node, a first NMOS transistor which is connected between the first output node and the ground voltage, the gate of which is connected to the first node, a second PMOS transistor which is connected between the supply voltage and the second output node, the gate of which gate is connected to the second node, a second NMOS transistor which is connected between the second output node and the ground voltage, the gate of which is connected to the second node, a first inverter, an input terminal of which is connected to the first output node and an output terminal of which is connected to the second output node and a second inverter, an input terminal of which is connected to the second output node and an output terminal of which is connected to the first output node.

### BRIEF DESCRIPTION OF THE DRAWINGS

The foregoing and other objects, features and advantages of the invention will be apparent from the more particular description of a preferred embodiment of the invention, as illustrated in the accompanying drawings in which like reference characters refer to the same parts throughout the different views. The drawings are not necessarily to scale, emphasis instead being placed upon illustrating the principles of the invention.

FIG. 1 is a circuit diagram of a general SAFF.

FIG. 2 is a circuit diagram of the SAFF according to a first embodiment of the present invention.

FIG. 3 is a circuit diagram of the SAFF according to a second embodiment of the present invention.

FIG. 4 is a circuit diagram of the SAFF according to a third embodiment of the present invention.

FIG. 5 is a circuit diagram of the SAFF according to a fourth embodiment of the present invention.

### DETAILED DESCRIPTION OF THE INVENTION

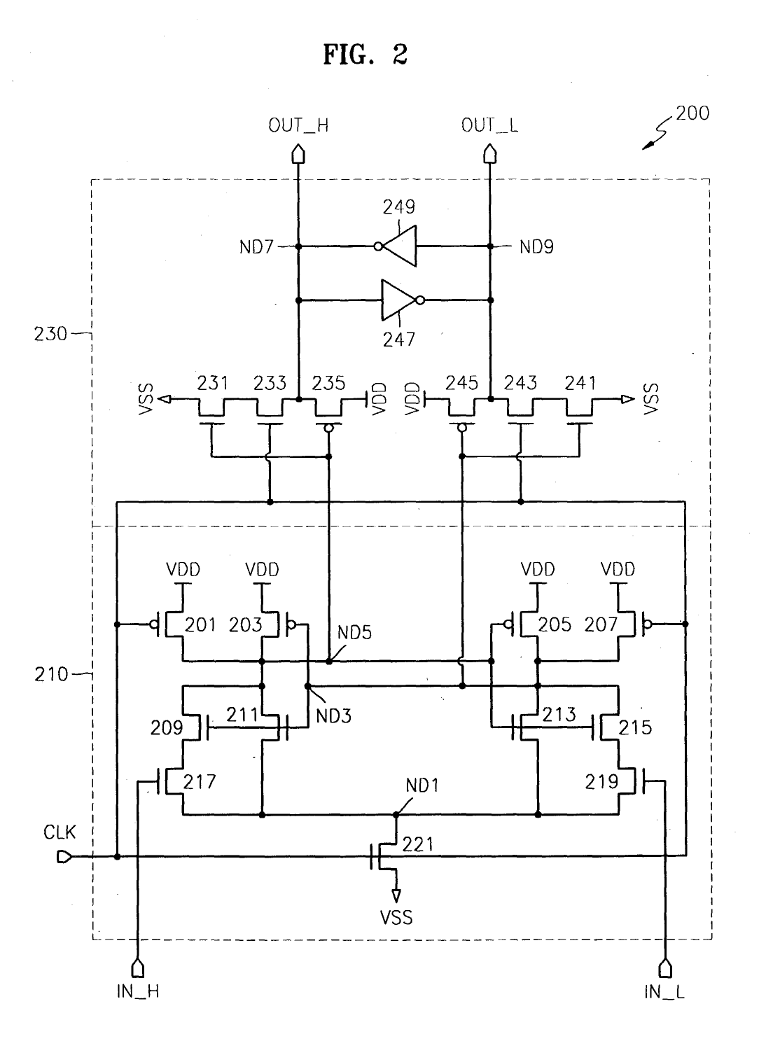

FIG. 2 is a circuit diagram of a SAFF according to a first embodiment of the present invention. Referring to FIG. 2, a SAFF 200 includes a sense amplifier 210 and a R-S latch 230.

The sense amplifier 210 includes a plurality of MOS transistors 201, 203, 205, 207, 209, 211, 213, 215, 217, 219 and 221. PMOS transistors 201 and 203 are connected between the supply voltage VDD and a first node ND5, and the clock signal CLK is inputted to the gate of the PMOS transistor 201. The gate of the PMOS transistor 203 is connected to a second node ND3.

The PMOS transistors 205 and 207 are connected between the supply voltage VDD and the second node ND3, and the clock signal CLK is inputted to the gate of the PMOS transistor 207. The gate of the PMOS transistor 205 is connected to the first node ND5.

NMOS transistors 209 and 217 are connected in series, and an NMOS transistor 211 is connected between the first node ND5 and a third node ND1, and the gates of the NMOS transistors 209 and 211 are connected to the second node ND3. A first input signal IN_H is inputted to the gate of an NMOS transistor 217.

NMOS transistors 215 and 219 are connected in series, and an NMOS transistor 213 is connected between the second node ND3 and the third node ND1, and the gates of, the NMOS transistors 213 and 215 are connected to the first node ND5. A second input signal IN_L is inputted to the gate of an NMOS transistor 219. The first input signal IN_H and the second input signal IN_L are complementary signals or differential signals.

An NMOS transistor 221 is connected between the third node ND1 and the ground voltage VSS, and the clock signal CLK is inputted to the gate of the NMOS transistor 221.

An R-S latch 230 includes a plurality of MOS transistors 231, 233, 235, 241, 243 and 245 and two inverters 247 and 249. Two NMOS transistors 231 and 233 connected in series are connected between a first output node ND7 and the ground voltage VSS, and a PMOS transistor 235 is connected between the supply voltage VDD and the first output node ND7.

The gate of the PMOS transistor 235 and the gate of the NMOS transistor 231 are both connected to the first node ND5, and the gate of the NMOS transistor 233 receives the clock signal CLK. NMOS transistors 231 and 233 connected in series fortify a falling transition of the SAFF 200.

Two NMOS transistors 241 and 243, which are also connected in series, are connected between the second output node ND9 and the ground voltage VSS, and a PMOS transistor 245 is connected between the supply voltage VDD and the second output node ND9.

The gate of the PMOS transistor 245 and the gate of the NMOS transistor 241 are both connected to the second node ND3, and the gate of the NMOS transistor 243 receives the clock signal CLK. The NMOS transistors 241 and 243 connected in series fortify a falling transition of the SAFF 200.

The input node and the output node of an inverter 247 are connected to the first output node ND7 and the second output node ND9, respectively, and the input node and the output node of the inverter 249 are connected to the second output node ND9 and the first output node ND7, respectively. A first output signal OUT_H is a signal of the first output node ND7 and a second output node OUT_L is a signal of the second output node ND9.

The first output node ND7 and the second output node OUT_L are complementary signals or differential signals. The inverters 247 and 249 latch a signal of the first output node ND7 and a signal of the second output node ND9, respectively.

Referring to FIG. 2, the operation of the SAFF 200 will now be described. The sense amplifier 210 precharges the nodes ND3 and ND5 with the supply voltage level VDD while the clock signal CLK is at a low level.

The above process is called a precharging phase, in which the NMOS transistors 221, 233 and 243 are turned off and PMOS transistor 235 and 245 are turned off in response to corresponding nodes ND3 and ND5, respectively.

While the clock signal CLK is at logic high level, the sense amplifier 210 receives and senses the differential input signals IN_L and IN_H and outputs the sensed differential input signals to the R-S latch 230. This process is called an evaluation phase.

In the evaluation phase, if the first input signal IN_H is at logic high level and the second input signal IN_L is at the logic low level, the operation of the sense amplifier 210 will be as follows. The NMOS transistors 217 and 221 are turned on and the NMOS transistor 219 is turned off, and so the NMOS transistor 209 is turned on.

Therefore, a voltage of the first node ND5 is pulled down to the logic low level through the transistors 209, 217 and 221. In this case, the PMOS transistor 205 is turned on in response to the voltage of the first node ND5, and so a voltage of the second node ND3 is maintained at the supply voltage level VDD.

The PMOS transistor 235 of the R-S latch 230 is turned on and when the NMOS transistor 231 is turned off, the voltage of the first node ND5 is at the logic low level, so that a voltage of the first output node ND7 is pulled up to the level of the supply voltage VDD.

In addition, the PMOS transistor 245 is turned off and when a the NMOS transistor 241 is turned on, the voltage of the second node ND3 is at the logic high level, so that a voltage of the second output node ND9 is pulled down to the ground voltage VSS.

Therefore, the voltages of the first and second output nodes ND7 and ND9 are latched by the inverters 247 and 249, respectively, so that the first output signal OUT_H goes to the logic high level and the second output signal OUT_L goes to the logic low level. The voltages of the first and second output nodes ND7 and ND9 are maintained until immediately before the next evaluation phase.

In the evaluation phase, if the first input signal IN_H is at the logic low level and the second input signal IN_L is at the logic high level, the second node ND3 of the sense amplifier 210 transits to the logic low level from the supply voltage VDD, and the first node ND5 is maintained at the level of the supply voltage VDD.

The first output node ND7 of the R-S latch 230 is pulled down to the ground voltage VSS by NMOS transistors 231 and 233. The second output node ND9 is pulled up to the supply voltage VDD by the PMOS transistor 245. Therefore, the first output signal OUT_H is at the logic low level and the second output signal OUT_L is at the logic high level.

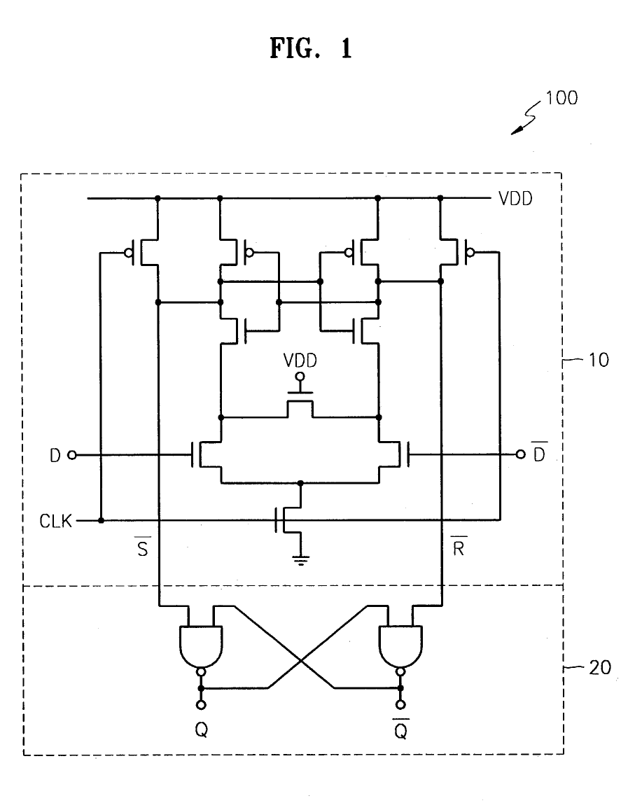

In the SAFF 200 according to the present invention, a falling transition is fortified by two pairs of NMOS transistors 231 and 233, and 241 and 243 connected in series. Thus, the SAFF 200 is capable of performing high-speed operation in comparison to the SAFF 100 of FIG. 1.

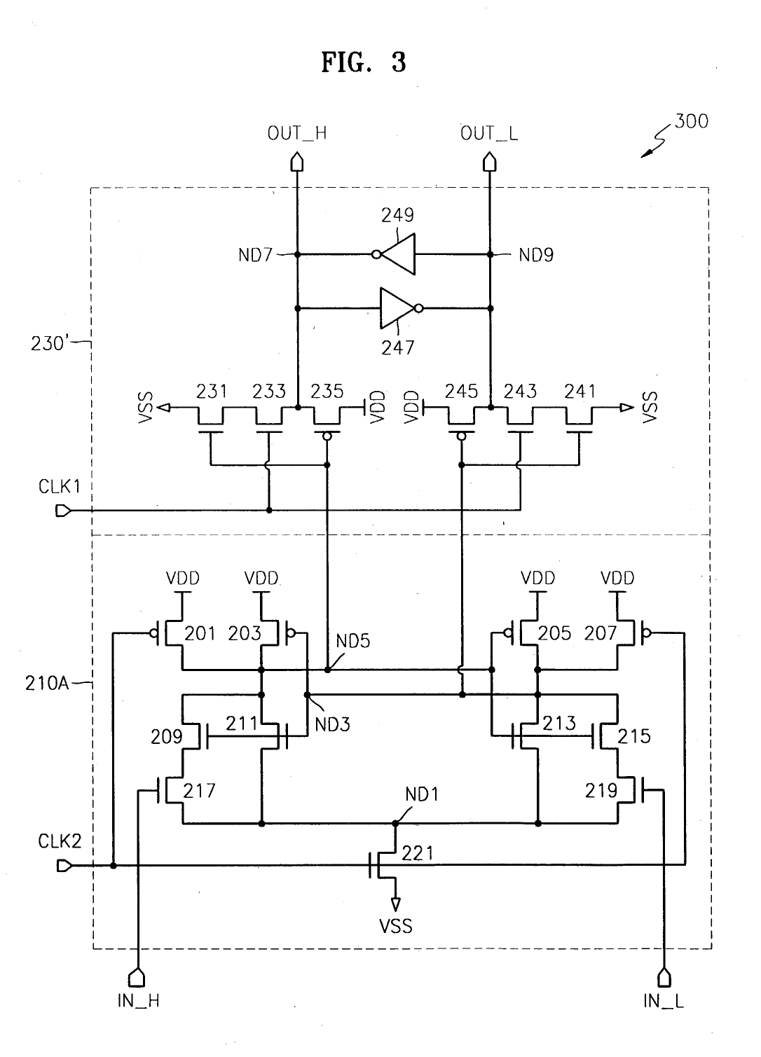

FIG. 3 is a circuit diagram of a SAFF 300 according to a second embodiment of the present invention. The SAFF 300 of FIG. 3 is substantially the same as the SAFF 200 of FIG. 2, except that the SAFF 300 uses a first clock signal CLK1 and a second clock signal CLK2. The SAFF 300 of FIG. 3 includes a sense amplifier 210A and a R-S latch 230′.

Briefly, the configuration of the R-S latch 230′ of FIG. 3 is same as the configuration of the R-S latch 230 of FIG. 2, except that the first clock signal CLK1 is inputted to the gates of the respective NMOS transistors 233 and 243.

Further, the configuration of the sense amplifier 210A of FIG. 3 is same as the configuration of the sense amplifier 210 of FIG. 2, except that the second clock signal CLK2 is inputted to the gates of the respective NMOS transistors 201, 207 and 221.

In the precharging phase, the first clock signal CLK1 and the second clock signal CLK2 are maintained at the logic low level. In the evaluation phase, the first clock signal CLK1 and the second clock signal CLK2 are maintained at the logic high level.

Since the SAFF 300 of FIG. 3 senses, amplifies and detects differential input signals IN_H and IN_L and outputs the differential output signals OUT_H and OUT_L in the same manner as the SAFF 200 of FIG. 2, corresponding descriptions will be omitted.

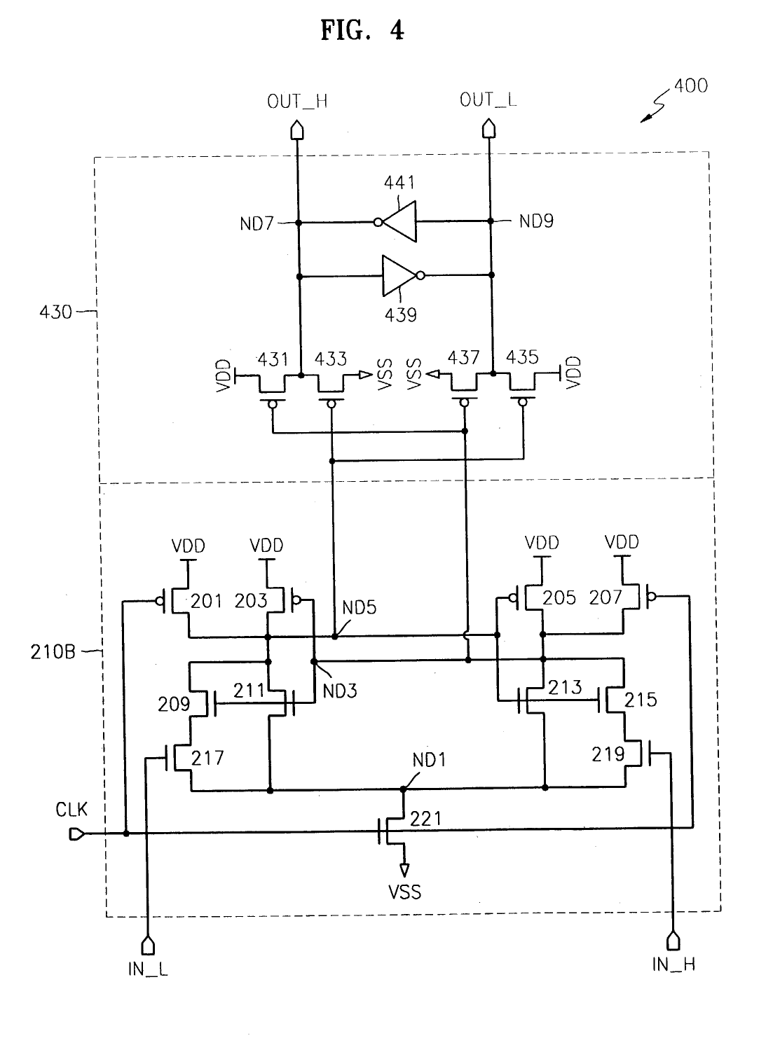

FIG. 4 is a circuit diagram of a SAFF 400 according to a third embodiment of the present invention. Referring to FIG. 4, the SAFF 400 includes a sense amplifier 210B and an R-S latch 430.

The sense amplifier 210B includes a plurality of MOS transistors 201, 203, 205, 207, 209, 211, 213, 215, 217, 219 and 221. PMOS transistors 201 and 203 are connected between the supply voltage VDD and the first node ND5, and the clock signal CLK is inputted to the gate of the PMOS transistor 201. The gate of the PMOS transistor 203 is connected to the second node ND3.

The PMOS transistors 205 and 207 are connected between the supply voltage VDD and the second node ND3, and the clock signal CLK is inputted to the gate of the PMOS transistor 207. The gate of the PMOS transistor 205 is connected to the first node ND5.

The NMOS transistors 209 and 217 are connected in series, and the NMOS transistor 211 is connected between the first node ND5 and the third node ND1. A respective gate of the NMOS transistors 209 and 211 is connected to the second node ND3. The second input signal IN_L is inputted to the gate of the NMOS transistor 217.

The NMOS transistors 215 and 219 are connected in series, and the NMOS transistor 213 is connected between the second node ND3 and the third node ND1. A respective gate of the NMOS transistors 213 and 215 is connected to the third node ND1. The first input signal IN_H is inputted to the gate of the NMOS transistor 219. The first input signal IN_H and the second input signal IN_L are complementary signals or differential signals.

The NMOS transistor 221 is connected between the third node ND1 and the ground voltage VSS, and the clock signal CLK is inputted to the gate of the NMOS transistor 221.

An R-S latch 430 includes a plurality of PMOS transistors 431, 433, 435 and 437. The PMOS transistor 431 is connected between the supply voltage VDD and the first output node ND7. The gate of the PMOS transistor 431 is connected to the second node ND3. The PMOS transistor 433 is connected between the first output node ND7 and the ground voltage VSS. The gate of the PMOS transistor 433 is connected to the first node ND5.

The PMOS transistor 435 is connected between the supply voltage VDD and the second output node ND9. The gate of the PMOS transistor 435 is connected to the first node ND5. The PMOS transistor 437 is connected between the second output node ND9 and the ground voltage VSS. The gate of the PMOS transistor 437 is connected to the second node ND3.

The input node and the output node of an inverter 439 are connected to the first output node ND7 and the second output node ND9, respectively. The input node and the output node of an inverter 441 are connected to the second output node ND9 and the first output node ND7, respectively. The inverters 439 and 441 constitute a latch.

Referring to FIG. 4, the operation of the SAFF 400 will be described briefly as follows. In a precharging phase, nodes ND3 and ND5 are precharged with the supply voltage VDD.

In an evaluation phase, if the first input signal IN_H is at the logic high level and the second input signal IN_L is at the logic low level, NMOS transistors 219 and 221 are turned on and the NMOS transistor 217 is turned off, so that the NMOS transistor 215 is turned on.

Therefore, a voltage of the second node ND3 is pulled down to the logic low level through the transistors 215, 219 and 221. In this case, the PMOS transistor 203 is turned on in response to the voltage of the second node ND3, and so a voltage of the first node ND5 is maintained at the level of the supply voltage VDD.

The PMOS transistors 433 and 435 are turned off when the voltage of the first node ND5 is at the logic high level. However, the PMOS transistors 431 and 437 are turned on when the voltage of the second node ND3 is at the logic low level, so that first output node ND7 is pulled up to the supply voltage VDD and the second output node ND9 is pulled down to the ground voltage VSS.

Therefore, the voltages of the respective output nodes ND7 and ND9 are latched by the inverters 439 and 441, respectively, so that the first output signal OUT_H goes to the logic high level and the second output signal OUT_L goes to the logic low level. Then voltages of the respective first and second output nodes ND7 and ND9 are maintained immediately before the next evaluation phase.

In the evaluation phase, if the first input signal IN_H is at the logic low level and the second input signal IN_L is at the logic high level, the second node ND3 of the sense amplifier 210B is maintained at the level of the supply voltage VDD and the first node ND5 transits to the logic low level from the supply voltage VDD.

The first output node ND7 is pulled down to the ground voltage VSS by the PMOS transistor 433. The second output node ND9 is pulled up to the level of the supply voltage VDD by the PMOS transistor 435. In the SAFF 400 according to the third embodiment of the present invention, the R-S latch 430 can be implemented with four PMOS transistors, so that the operating speed of the SAFF 400 can be improved. Also, the overall layout area of the SAFF 400 can be reduced.

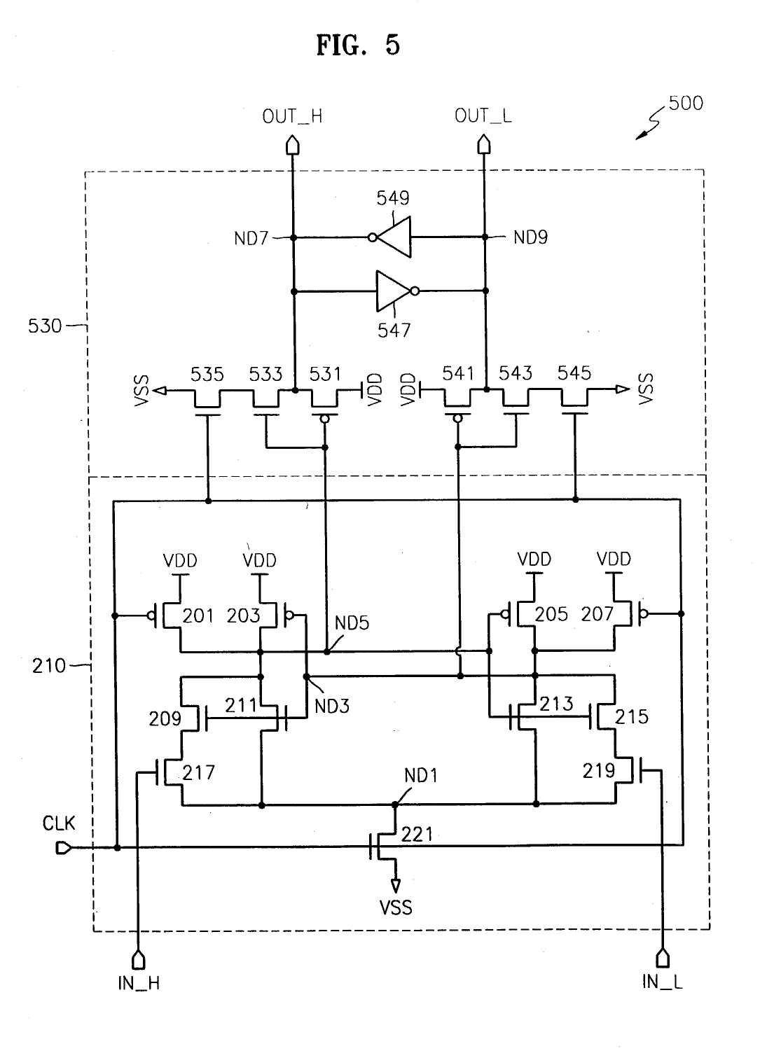

FIG. 5 is a circuit diagram of a SAFF according to a fourth embodiment of the present invention. Referring to FIG. 5, a SAFF 500 includes a sense amplifier 210 and an R-S latch 530. The configuration and operation of the sense amplifier 210 of FIG. 5 are the same as those of the sense amplifier 210 of FIG. 2.

The R-S latch 530 includes a plurality of MOS transistors 531, 533, 535, 541, 543 and 545 and two inverters 547 and 549.

A PMOS transistor 531 is connected between the supply voltage VDD and the first output node ND7. The gate of the PMOS transistor 531 is connected to the first node ND5. The NMOS transistors 533 and 535, which are also connected in series, are connected between the first output node ND7 and the ground voltage VSS. The gate of the NMOS transistor 533 is connected to the first node ND5, and the clock signal CLK is inputted to the gate of the NMOS transistor 535.

The PMOS transistor 541 is connected between the supply voltage VDD and the second output node ND9. The gate of the PMOS transistor 541 is connected to the second node ND3. The NMOS transistors 543 and 545, which are also connected in series, are connected between the second output node ND9 and the ground voltage VSS. The gate of the NMOS transistor 543 is connected to the second node ND3, and the clock signal CLK is inputted to the gate of the NMOS transistor 545.

The input node and the output node of an inverter 547 are connected to the first output node ND7 and the second output node ND9, respectively. The input node and the output node of an inverter 549 are connected to the second output node ND9 and the first output node ND7, respectively.

In the precharging phase, node ND3 and ND5 are precharged with the supply voltage VDD, the NMOS transistors 535 and 545 of the R-S latch 530 are turned off.

In the evaluation phase, if the first input signal IN_H is at the logic high level and the second input signal IN_L is at the logic low level, a voltage of the first node ND5 is pulled down to a low level by the transistors 209, 217 and 221. In this case, the PMOS transistor 205 is turn on in response to the voltage of the first node ND5, so that the voltage of the second node ND3 is maintained at the level of the supply voltage VDD.

The PMOS transistor 531 of the R-S latch 530 is turned on in response to the voltage of the second node ND3 at the logic high level and the NMOS transistors 543 and 545 are turned on, so that the voltage of the second output node ND9 is pulled down to the level of the ground voltage VSS.

Therefore, the voltages of the respective output nodes ND7 and ND9 are latched by the inverters 547 and 549, so that the first output signal OUT_H goes to the logic high level and the second output signal OUT_L goes to the logic low level. The voltages of the respective output nodes ND7 and ND9 are maintained continuously immediately before the next evaluation phase.

In addition, in the evaluation phase, if the first input signal IN_H is at the low level and the second input signal IN_L is at the high level, the second node ND3 of the sense amplifier 210 transits to low level from the level of the supply voltage VDD and the first node ND5 is maintained at the level of the supply voltage VDD.

The first output node ND7 of the R-S latch 230 is pulled down to the level of the ground voltage VSS by the NMOS transistors 533 and 535. The second node ND9 is pulled up to the level of the supply voltage VDD by the PMOS transistor 541. Therefore, the first output signal OUT_H is at the logic low level and the second output signal OUT_L is at the logic high level.

As described above, the SAFF according to the present invention does not use a NAND gate, so that a clock-to-output delay can be reduced. Therefore, the SAFF according to the present invention can operate at high speed.

The R-S latch of the SAFF according to the present invention can be embodied with a plurality of MOS transistors. Thus, the overall layout area can also be reduced.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. A flip-flop comprising:
a sense amplifier which includes a first node and a second node, the first node and the second node being precharged with a supply voltage when a clock signal is in a first state, and the sense amplifier receiving and amplifying differential input signals when the clock signal is in a second state, such that differential output signals are output to the first node and the second node; and
a latch circuit which is connected to the first node and the second node of the sense amplifier, the latch circuit detecting and latching the differential input signals according to the state of the clock signal and the differential output signals.

2. The flip-flop of claim 1, wherein the latch circuit comprises:
a first output node;
a second output node;
a first pull-up circuit which pulls up the first output node to a supply voltage in response to a signal of the first node;
a second pull-up circuit which pulls up the second output node to the supply voltage in response to a signal of the second node;
a first pull-down circuit which pulls down the first output node to a ground voltage in response to the signal of the first node and the state of the clock signal;
a second pull-down circuit which pulls down the second output node to the ground voltage in response to the signal of the second node and the state of the clock signal; and
a data latch circuit which latches a signal of the first output node and a signal of the second output node.

3. The flip-flop of claim 1, wherein the latch circuit comprises:
a first output node;
a second output node;
a first PMOS transistor connected between the supply voltage and the first output node, a gate of the first PMOS transistor being connected to the first node of the sense amplifier;
a first NMOS transistor and a second NMOS transistor which are connected in series between the first output node and a ground voltage;
a second PMOS transistor connected between the supply voltage and the second output node, a gate of the second PMOS transistor being connected to the second node of the sense amplifier;
a third NMOS transistor and a fourth NMOS transistor connected in series between the second output node and the ground voltage;
a first inverter, an input terminal of which is connected to the first output node and an output terminal of which is connected to the second output node; and
a second inverter, an input terminal of which is connected to the second output node and an output terminal of which is connected to the first output node;
wherein the clock signal is inputted to the gate of the first NMOS transistor and the gate of the third NMOS transistor, the gate of the second NMOS transistor is connected to the first node, and the fourth NMOS transistor is connected to the second node.

4. The flip-flop of claim 1, wherein the latch circuit comprises:
a first output node;
a second output node;
a first pull-down circuit which pulls down the first output node to a ground voltage in response to a signal of the first node;
a first pull-up circuit which pulls up the first output node to the supply voltage in response to the signal of the second node;
a second pull-down circuit which pulls down the second output node to the ground voltage in response to a signal of the second node;
a second pull-up circuit which pulls up the second output node to the supply voltage in response to the signal of the first node; and
a data latch circuit which latches a signal of the first output node and a signal of the second output node.

5. The flip-flop of claim 1, wherein the latch circuit comprises:
a first output node;
a second output node;
a first PMOS transistor connected between the supply voltage and the first output node, a gate of the first PMOS transistor being connected to the second node of the sense amplifier;
a second PMOS transistor connected between the first output node and the ground voltage, a gate of the second PMOS transistor being connected to the first node;
a third PMOS transistor which is connected between the supply voltage and the second output node, a gate of the third PMOS transistor being connected to the first node;
a fourth PMOS transistor connected between the second output node and the ground voltage, a gate of the fourth PMOS transistor being connected to the second node of the sense amplifier;
a first inverter, an input terminal of which is connected to the first output node and an output terminal of which is connected to the second output node; and
a second inverter, an input terminal of which is connected to the second output node and an output terminal of which is connected to the first output node.

6. A flip-flop comprising:
a sense amplifier which includes a first node and a second node, the first node and the second node being precharged with a supply voltage when a first clock signal is in a first state, and the sense amplifier receiving and amplifying differential input signals when the first clock signal is in a second state, such that differential output signals are output to the first node and the second node; and
a latch circuit which is connected to the first node and the second node of the sense amplifier, and which detects and latches the differential input signals according to the state of the second clock signal and the differential output signals.

7. The flip-flop of claim 6, wherein the latch circuit comprises:
a first output node;
a second output node;
a first pull-up circuit which pulls up the first output node to a supply voltage in response to a signal of the first node;
a second pull-up circuit which pulls up the second output node to the supply voltage in response to a signal of the second node;
a first pull-down circuit which pulls down the first output node to a ground voltage in response to the signal of the first node and the state of the second clock signal;
a second pull-down circuit which pulls down the second output node to the ground voltage in response to the signal of the second node and the state of the second clock signal; and
a data latch circuit which latches a signal of the first output node and a signal of the second output node.

8. A flip-flop comprising:
a sense amplifier which includes a pair of input nodes and a pair of output nodes that are precharged with a supply voltage when a clock signal is in a first state, and the sense amplifier receiving and amplifying differential input signals inputted to the pair of input nodes when the clock signal is in a second state, so as to output differential output signals to the pair of output nodes; and
a latch circuit which is connected to the pair of output nodes of the sense amplifier, the latch circuit detecting and latching the differential input signals inputted to the pair of input nodes of the sense amplifier according to the state of the clock signal and the differential output signals from the pair of output nodes.

9. A flip-flop comprising:
a sense amplifier which senses and amplifies differential input signals inputted to a first input node and a second input node and outputs differential output signals, which are the results of the amplification, to a first node and a second node, in an evaluation mode; and
a latch circuit connected to the first node and the second node, which detects and latches the differential input signals according to the state of the differential output signals, in the evaluation mode.

10. The flip-flop of claim 9, wherein the flip-flop is characterized by precharging the first node and the second node with a supply voltage in a precharging mode;
wherein in the precharging mode, the latch circuit latches the detected differential input signals immediately before the next evaluation mode.

11. The flip-flop of claim 9, wherein the latch circuit comprises:
a first output node;
a second output node;
a first pull-up circuit which pulls up the first output node to a supply voltage in response to a signal of the first node;
a second pull-up circuit which pulls up the second output node to the supply voltage in response to a signal of the second node;
a first pull-down circuit which pulls down the first output node to a ground voltage in response to the signal of the first node;
a second pull-down circuit which pulls down the second output node to the ground voltage in response to the signal of the second node; and
a data latch circuit which latches a signal of the first output node and a signal of the second output node.

12. The flip-flop of claim 9, wherein the latch circuit comprises:
a first output node;
a second output node;
a first PMOS transistor which is connected between the supply voltage and the first output node, the gate of the first PMOS transistor being connected to the first node;
a first NMOS transistor which is connected between the first output node and the ground voltage, the gate of the first NMOS transistor being connected to the first node;
a second PMOS transistor which is connected between the supply voltage and the second output node, the gate of the second PMOS transistor being connected to the second node;
a second NMOS transistor which is connected between the second output node and the ground voltage, the gate of the second NMOS transistor being connected to the second node;
a first inverter, an input terminal of which is connected to the first output node and an output terminal of which is connected to the second output node; and
a second inverter, an input terminal of which is connected to the second output node and an output terminal of which is connected to the first output node.
